(19) United States
(12) Patent Application Publication
(10) Pub. No.: US 2016/0163381 A1
(43) Pub. Date: Jun. 9, 2016

(54) MEMORY SYSTEM INCLUDING SEMICONDUCTOR MEMORY DEVICE AND METHOD OF OPERATING THE SAME

(71) Applicant: SK hynix Inc., Gyeonggi-do (KR)

(72) Inventor: Jong Min LEE, Seoul (KR)

(21) Appl. No.: 14/713,695

(22) Filed: May 15, 2015

(30) Foreign Application Priority Data
Dec. 4, 2014 (KR) 10-2014-0173320

(51) Int. Cl. G11C 11/56; G06F 12/10; G11C 16/14

(52) U.S. Cl. CPC G11C 11/5635; G11C 16/14; G06F 12/1036; G06F 2212/1041; G06F 2212/202; G06F 2212/65

(57) ABSTRACT

A semiconductor memory device and a method of operating the same are provided. The method includes determining the number of valid pages of a first memory block as a first count value, determining the number of valid pages of a second memory block as a second count value, applying a weight to the first count value and generating a comparison count value which is greater than the first count value, and defining the first and second memory blocks as a victim block by comparing the comparison count value and the second count value with a threshold value.

### CROSS-REFERENCE TO RELATED APPLICATION

The present application claims priority to Korean patent application number 10-2014-0173320, filed on Dec. 4, 2014, the entire disclosure of which is herein incorporated by reference in its entirety.

### BACKGROUND

1. Field of Invention

The present invention relates to an electronic device, and more specifically, to a memory system including a semiconductor memory device and a method of operating the same.

2. Description of Related Art

Semiconductor memory devices are implemented using semiconductor materials such as silicon (Si), germanium (Ge), gallium arsenide (GaAs), indium phosphide (InP), or the like. Semiconductor memory devices are generally classified into those that are volatile and those that are non-volatile.

Volatile memory devices are memory devices that lose their data when their power supply is cut off. Volatile memory devices include static random access memory (SRAM), dynamic RAM (DRAM), synchronous DRAM (SDRAM), and the like. Non-volatile memory devices maintain their stored data even when their power supply is cut off. Non-volatile memory devices include read-only memory (ROM), programmable ROM (PROM), erasable programmable ROM (EPROM), electrically erasable programmable ROM (EEPROM), flash memory, phase-change RAM (PRAM), magnetic RAM (MRAM), resistive RAM (RRAM), ferroelectric RAM (FRAM), or the like. Flash memory is generally classified as being either NOR or NAND type.

Semiconductor memory devices include a plurality of memory blocks. Each of the plurality of memory blocks includes a plurality of memory cells. Each of the plurality of memory cells may be single-level cells or multi-level cells. Single-level cells store one bit of data, and multi-level cells store two or more bits of data.

### SUMMARY

Various embodiments are directed to a memory system having an improved speed and a method of operating the same.

One aspect of the present invention provides a method of operating a semiconductor memory device including a plurality of memory blocks, including: determining the number of valid pages of a first memory block including single-level cells as a first count value; determining the number of valid pages of a second memory block including multi-level cells as a second count value; applying a weight to the first count value to generate a comparison count value which is greater than the first count value; and defining at least one of the first and second memory blocks as a victim block by comparing the comparison count value and the second count value with a threshold value.

As an embodiment, the comparison count value is obtained by multiplying the first count value by 2 when two-bit data are stored in each of the memory cells of the second memory block.

As an embodiment, the comparison count value may be obtained by multiplying the first count value by n when n-bit data is stored in each of the memory cells of the second memory block, where n is an integer, which is greater than two.

As an embodiment, the first memory block may be the victim block when the comparison count value is less than or equal to the threshold value.

As an embodiment, the second memory block may be the victim block when the second count value is less than or equal to the threshold value.

The method of operating the semiconductor memory device may further include: storing data of valid pages of the victim block in a third memory block among the plurality of memory blocks. The method of operating the semiconductor memory device may further include: erasing the data of the valid pages of the victim block.

Another aspect of the present invention provides a memory system including: at least one semiconductor memory device including a first memory block including single-level cells and a second memory block including multi-level cells; and a controller suitable for determining the number of valid pages of the first memory block as a first count value and the number of valid pages of the second memory block as a second count value, generating a comparison count value which is greater than the first count value by applying a weight to the first count value, and defining at least one of the first and second memory blocks as a victim block by comparing the comparison count value and the second count value with a threshold value.

As an embodiment, the controller may generate the comparison count value by multiplying the first count value by 2 when two-bit data are stored in each of the memory cells of the second memory block.

As an embodiment, the controller may generate the comparison count value by multiplying the first count value by n when n-bit data is stored in each of the memory cells of the second memory block, where n is an integer, which is greater than two.

As an embodiment, the controller may define the first memory block as the victim block when the comparison count value is less than or equal to the threshold value. Further, the controller may define the second memory block as the victim block when the second count value is less than or equal to the threshold value.

As an embodiment, the semiconductor memory device may further include a third memory block in which the controller may store data of valid pages of the victim block.

As an embodiment, the controller may include: a processing unit; and a random access memory (RAM), and the processing unit may store a map table including a mapping relation between physical block addresses and logical block addresses, which correspond to the valid pages of the first and second memory blocks, in the RAM.

As an embodiment, the processing unit may store the first and second count values in the RAM, and adjust the first and second count values when each of the valid pages of the first and second memory blocks is invalidated. The processing unit may decrease the first and second count values when each of the valid pages of the first and second memory blocks is invalidated

Still another aspect of the present invention provides a memory system including: at least one semiconductor memory device including a first memory block including each of memory cells of storing n-bit data and a second memory block including each of memory cells storing m-bit data, wherein n is an integer, and m is an integer greater than n; and a controller suitable for determining the number of valid pages of the first memory block as a first count value and the number of valid pages of the second memory block as a second count value, generating a comparison count value which is greater than the first count value by applying a weight to the first count value, and defining at least one of the first and second memory blocks as a victim block by comparing the comparison count value and the second count value with a threshold value.

As an embodiment, the weight may be a value obtained by dividing m into n (i.e. weight=m/n).

As an embodiment, the controller may define the first memory block as the victim block when the comparison count value is less than or equal to the threshold value, and define the second memory block as the victim block when the second count value is less than or equal to the threshold value.

As an embodiment, the controller may comprise: a random access memory (RAM) suitable for including a map table storing a mapping relation between physical block addresses and logical block addresses, which correspond to the valid pages of the first and second memory blocks, and a count table storing the first and second count values; and a processing unit suitable for updating the mapping relation, and decreasing the first and second count values when each of the valid pages of the first and second memory blocks is invalidated.

### BRIEF DESCRIPTION OF THE DRAWINGS

FIG. 1 is a block diagram illustrating a memory system according to an exemplary embodiment of the present invention;

FIG. 2 is a diagram illustrating memory blocks included in a semiconductor memory device of FIG. 1;

FIG. 3 is a block diagram illustrating a memory system according to an exemplary embodiment of the present invention;

FIG. 4 is a diagram describing memory blocks included in each of semiconductor memory devices of FIG. 3;

FIG. 5 is a table illustrating a count table according to an exemplary embodiment of the present invention;

FIG. 6 is a conceptual diagram illustrating logical pages included in any one of memory blocks according to an exemplary embodiment of the present invention;

FIG. 7 is a flowchart describing an operating method of a controller according to an exemplary embodiment of the present invention;

FIG. 8 is a diagram describing count values compared with a threshold value according to an exemplary embodiment of the present invention;

FIG. 9 is a conceptual diagram describing an example in which at least one victim block is selected according to an exemplary embodiment of the present invention; and

FIG. 10 is a block diagram illustrating a memory system according to an exemplary embodiment of the present invention.

### DETAILED DESCRIPTION

Exemplary embodiments of the present invention will be described more fully hereinafter with reference to the accompanying drawings. In the specification, only what is needed for understanding the present invention will be included, and other information will be omitted to not obscure the subject matter of the present invention. Further, the present invention may be embodied in different forms and should not be construed as limited to the embodiments set forth herein. Exemplary embodiments of the present invention are described below in sufficient detail with reference to accompanying drawings to enable those of ordinary skill in the art to embody and practice the present invention.

Throughout the specification, it will be understood that when an element is referred to as being “connected” or “coupled” to another element, it can be directly connected or coupled to the other element or intervening elements may be present. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

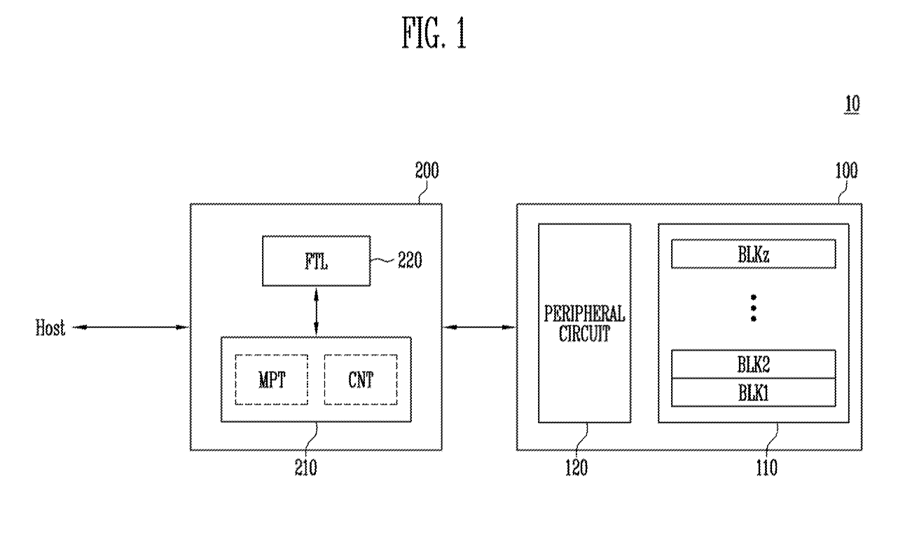

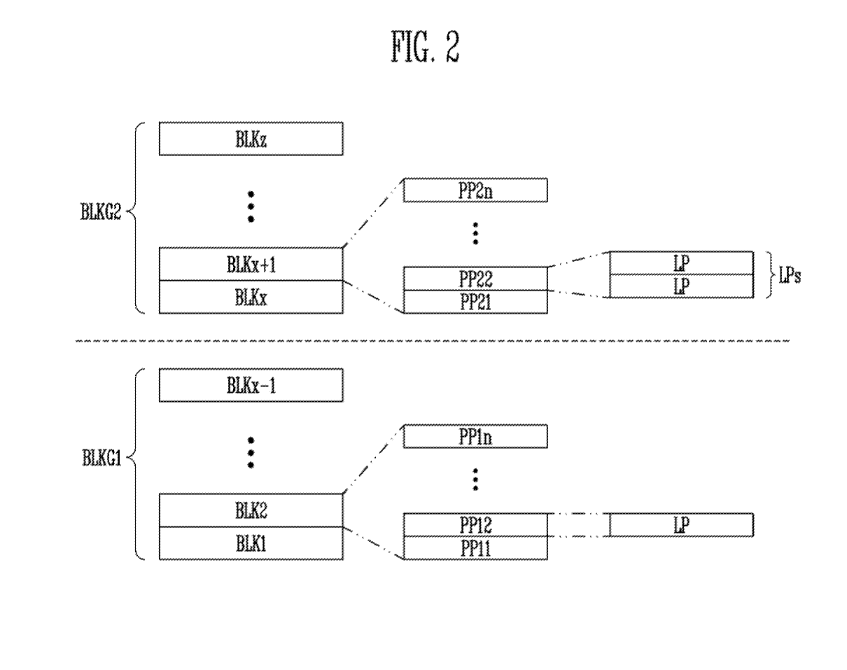

FIG. 1 is a block diagram illustrating a memory system 10 according to an exemplary embodiment of the present invention. FIG. 2 is a diagram illustrating memory blocks BLK1 to BLKz included in a semiconductor memory device 100 of FIG. 1.

Referring to FIG. 1, the memory system 10 may include the semiconductor memory device 100 and a controller 200.

The semiconductor memory device 100 may operate under the control of the controller 200. The semiconductor memory device 100 may include a memory cell array 110, and a peripheral circuit 120 for driving the memory cell array 110. The memory cell array 110 may include a plurality of memory blocks BLK1 to BLKz. Each of the plurality of memory blocks BLK1 to BLKz may include a plurality of memory cells.

As an embodiment, each memory block may include single-level cells or multi-level cells. Each of the memory cells included in a portion of the plurality of memory blocks BLK1 to BLKz may be defined as a single-level cell for storing one bit of data. The single-level cell stores one bit of data per memory cell. Each of the memory cells included in another portion of the plurality of memory blocks BLK1 to BLKz may be multi-level cells storing multi-bit data. The multi-level cell may store multiple bits of data in one memory cell.

Referring to FIG. 2, the plurality of memory blocks BLK1 to BLKz may be divided into first and second memory block groups BLKG1 and BLKG2. The first memory block group BLKG1 may include first to (x−1)-th memory blocks BLK1 to BLKx−1. Memory cells included in the first to (x−1)-th memory blocks BLK1 to BLKx−1 may be defined as the single-level cells. Each of the memory blocks BLK1 to BLKx−1 of the first memory block group BLKG1 may include first to n-th physical pages PP11 to PP1n, each of which may correspond to one logical page LP. Bits of data stored in the memory cells configuring one physical page may configure one logical page.

The second memory block group BLKG2 may include x-th to z-th memory blocks BLKx to BLKz. Memory cells included in the x-th to z-th memory blocks BLKx to BLKz may be defined as the multi-level cells. Each of the memory blocks BLKx to BLKz of the second memory block group BLKG2 may include first to n-th physical pages PP21 to PP2n, each of which may correspond to two or more logical pages LPs. For example, least significant bits of data stored in the memory cells configuring one physical page may configure one logical page, and most significant bits of data stored in corresponding memory cells may configure another logical page.

That is, the physical page of the first memory block group BLKG1 may correspond to one logical page LP, and the physical page of the second memory block group BLKG2 may correspond to a plurality of logical pages LPs. Hereinafter, for convenience of explanation, assume that each of the memory cells of the x-th to z-th memory blocks BLKx to BLKz stores two-bit data.

Referring to FIG. 1 again, the peripheral circuit 120 may be connected to the memory cell array 110. The peripheral circuit 120 may operate under the control of the controller 200. The peripheral circuit 120 may program data in the memory cell array 110, read the data from the memory cell array 110, and erase the data of the memory cell array 110, under the control of the controller 200.

As an embodiment, a read operation and a program operation of the semiconductor memory device 100 may be performed in units of logical pages. An erase operation of the semiconductor memory device 100 may be performed in units of memory blocks.

In the program operation, the peripheral circuit 120 may receive write data and a physical block address from the controller 200. One memory block and one physical page included therein may be designated by the physical block address. The logical page corresponding to the physical page may be designated by the physical block address. The peripheral circuit 120 may program the write data in the corresponding physical page. For example, the write data may be stored as the least significant bits of data of the corresponding physical page. For example, the write data may be stored as the most significant bits of data of the corresponding physical page.

In the read operation, the peripheral circuit 120 may receive the physical block address from the controller 200. One memory block and the physical page included therein may be designated by the physical block address. The logical page corresponding to the physical page may be designated by the physical block address. The peripheral circuit 120 may read the least significant bits or the most significant bits of data from the corresponding physical page, and output the read data to the controller 200.

In the erase operation, the physical block address transmitted from the controller 200 to the peripheral circuit 120 may designate one memory block. The peripheral circuit 120 may erase data of the memory block corresponding to the physical block address.

In an embodiment, the semiconductor memory device 100 may be a flash memory device.

The controller 200 may include a flash translation layer (FTL) 220.

The controller 200 may control various operations of the semiconductor memory device 100. The controller 200 may access the semiconductor memory device 100 in response to a request from a host. For example, the controller 200 may control the read, write, erase, and background operations of the semiconductor memory device 100. The controller 200 may provide an interface between the semiconductor memory device 100 and the host. The controller 200 may drive firmware for controlling the semiconductor memory device 100.

A random access memory (RAM) 210 may operate under the control of the flash translation layer (FTL) 220. The RAM 210 may store a map table MPT. The map table MPT may store a mapping relation between a logical block address and the physical block address.

According to an embodiment of the present invention, the RAM 210 may further store a count table CNT. The count table CNT may include a count value corresponding to each memory block. The count value may represent the number of valid pages in a corresponding memory block.

As an embodiment, the RAM 210 may be a static random access memory (SRAM), a dynamic random access memory (DRAM), a synchronous DRAM (SDRAM), etc.

As an embodiment, the RAM 210 may serve as an operating memory of the FTL 220. As an embodiment, the RAM 210 may serve as a buffer memory between the semiconductor memory device 100 and the host. For example, in the read operation, data read from the semiconductor memory device 100 may be temporarily stored in the RAM 210, and be output to the host. In the program operation, write data received from the host may be temporarily stored in the RAM 210, and be provided to the semiconductor memory device 100.

The FTL 220 may access the semiconductor memory device 100 in response to a request from the host. A program request of the program operation from the host may include the logical block address and write data. A read request of the read operation from the host may include the logical block address.

When the program request is received, the FTL 220 may convert the logical block address into the physical block address. The FTL 220 may provide the physical block address, the write data, and a command for controlling the program operation to the semiconductor memory device 100. The FTL 220 may update a mapping relation between the logical block address and the physical block address in the map table MPT.

When the read request is received, the FTL 220 may convert the logical block address into the physical block address with reference to the map table MPT, and provide the physical block address and a command for controlling the read operation to the semiconductor memory device 100.

Suppose that the program request of the program operation on the logical block address in which the program operation is already performed is received again. That is, suppose that an update operation on data corresponding to an arbitrary logical block address is requested. The FTL 220 may delete the mapping relation between a corresponding logical block address and a first physical block address in the map table MPT, and map the corresponding logical block address and a second physical block address, which is new. That is, the FTL 220 may update a mapping relation between the corresponding logical block address and the second physical block address in the map table MPT, and invalidate data of the logical page corresponding to the first physical block address. For example, a meta field corresponding to each physical block address in the map table MPT may be provided, and the data corresponding to the first physical block address may be invalidated by writing an invalid mark in the meta field corresponding to the first physical block address. In this case, data of the logical page corresponding to the first physical block address may be treated as invalid data. Accordingly, the logical page in the memory cell array 110 corresponding to the first physical block address may be defined as an invalid page. The logical page corresponding to the second physical block address may be defined as a valid page.

According to the embodiment, the FTL 220 may store and manage the count table CNT to the RAM 210.

The count table CNT may store the number of the valid pages of each memory block as the count value. The number of the valid pages of each memory block may be counted in various manners.

As an embodiment, the FTL 220 may process the program request, and decrease the count value of the memory block in which the invalid logical page is included whenever the update operation on the data corresponding to the arbitrary logical block address is requested.

As an embodiment, each logical page in the memory cell array 110 may include a flag bit that determines whether a corresponding logical page is a valid page or an invalid page. The FTL 220 may count the number of the valid pages of each memory block based on the flag bit of each logical page.

As an embodiment, the FTL 220 may count the number of the valid pages of each memory block by scanning the meta field corresponding to each physical block address in the map table MPT.

The FTL 220 may perform a garbage collection as the background operation. The FTL 220 may select at least one among the first to z-th memory blocks BLK1 to BLKz as a victim block, and select any one among the first to z-th memory blocks BLK1 to BLKz as a target block. The FTL 220 may read the valid pages in the victim block, and program the read data in the target block.

At this time, it may be desirable that the memory block including the small number of the valid pages is selected as the victim block.

For example, the memory block including the small number of valid pages may mean that a corresponding memory block includes a large number of the invalid pages. The corresponding memory block including the large number of the invalid pages may waste a lot of storage space. Accordingly, as the memory block including the small number of valid pages is selected as the victim block, the storage space of the semiconductor memory device 100 may be secured.

For example, the victim block including the small number of the valid pages may mean that less time is required for storing data stored in the valid pages in the target block. Accordingly, as the victim block includes the small number of the valid pages, a time required for the garbage collection may be decreased. This may mean that an operating speed of the memory system 10 is improved.

The FTL 220 may refer to the count value corresponding to each memory block in the count table CNT when selecting the victim block. According to an embodiment of the present invention, the victim block may be selected by applying different references to the count values of the first memory block group (BLKG1, refer to FIG. 2) including the single-level cells and the count values of the second memory block group (BLKG2, refer to FIG. 2) including the multi-level cells. In the second memory block group BLKG2, after the count values may be compared with a threshold value, a memory block having a count value greater than the threshold value may be selected as the victim block. On the other hand, in the first memory block group BLKG1, after a weight may be applied to the count values and comparison count values may be generated, a memory block having a comparison count value greater than the threshold value may be selected as the victim block. Accordingly, regardless of whether each memory block is a memory block including single-level cells or a memory block including multi-level cells, the victim block may be selected based on a ratio in which the valid pages among the logical pages of each memory block occupy.

When the victim block is selected by applying the same reference to the memory block including the single-level cells and the memory block including the multi-level cells, the memory block including the multi-level cells may have a number of logical pages greater than the memory block including the single-level cells. The number of valid pages of the memory block including the single-level cells and the number of valid pages of the memory block including multi-level cells may be compared with the same threshold value. In this case, although the ratio of the valid pages is high in the memory block including the single-level cells, the memory block including the single-level cells may be selected as the victim block, and although the ratio of the valid pages is low in the memory block including the multi-level cells, the memory block including the multi-level cells may not be selected as the victim block.

Before the garbage collection is performed, sufficient time for updating data corresponding to the logical pages of each memory block may be required. The data may be updated and the corresponding logical pages may be invalidated during this time. When sufficient time for updating the data corresponding to the logical pages of each memory block is not provided, the memory block may be selected as the victim block when the relatively small number of the logical pages is invalidated. In this case, compared with when the victim block is selected having a relatively large number of logical pages that are invalidated, the garbage collection may be frequently performed. This may mean that the operating speed of the memory system 10 is reduced.

According to an embodiment of the present invention, in a memory block including multi-level cells, whether the memory block is selected as the victim block may be determined by comparing the count value corresponding to the memory block including the multi-level cells with the threshold value. In a memory block including single-level cells, the weight may be applied to the count value corresponding to the memory block including single-level cells, the comparison count value may be generated, and whether to select the memory block as the victim block may be determined by comparing the comparison count value with the threshold value. The garbage collection on the memory block including the single-level cells may not be frequently performed. Accordingly, the memory system 10 having improved speed may be provided.

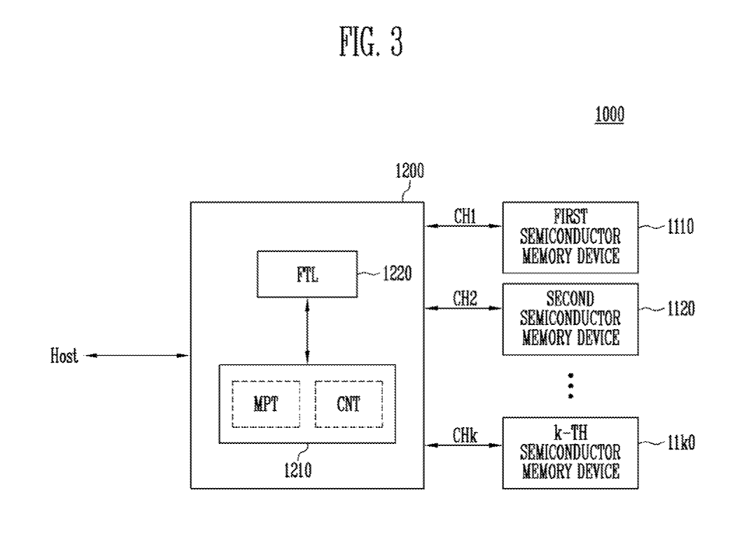

FIG. 3 is a block diagram illustrating a memory system 1000 according to an exemplary embodiment of the present invention.

Referring to FIG. 3, the memory system 1000 may include a plurality of semiconductor memory devices 1110 to 11k0 and a memory controller 1200.

Each of first to k-th semiconductor memory devices 1110 to 11k0 may have the same configuration and operation as the semiconductor memory device 100 described with reference to FIG. 1.

The memory controller 1200 may include a RAM 1210 and a flash translation layer (FTL) 1220.

The memory controller 1200 may communicate with the first to k-th semiconductor memory devices 1110 to 11k0 through first to k-th channels CH1 to CHk.

The FTL 1220 may have the same configuration and operation as the FTL 220 described with reference to FIG. 1.

The FTL 1220 may access the semiconductor memory devices 1110 to 11k0 in response to a request from the host. The FTL 1220 may update a mapping relation between a logical block address and a physical block address in a map table MPT. The FTL 1220 may store and manage a count table CNT in the RAM 1210. At this time, the count table CNT may store the number of valid pages of the memory block included in each of the semiconductor memory devices 1110 to 11k0 as the count value.

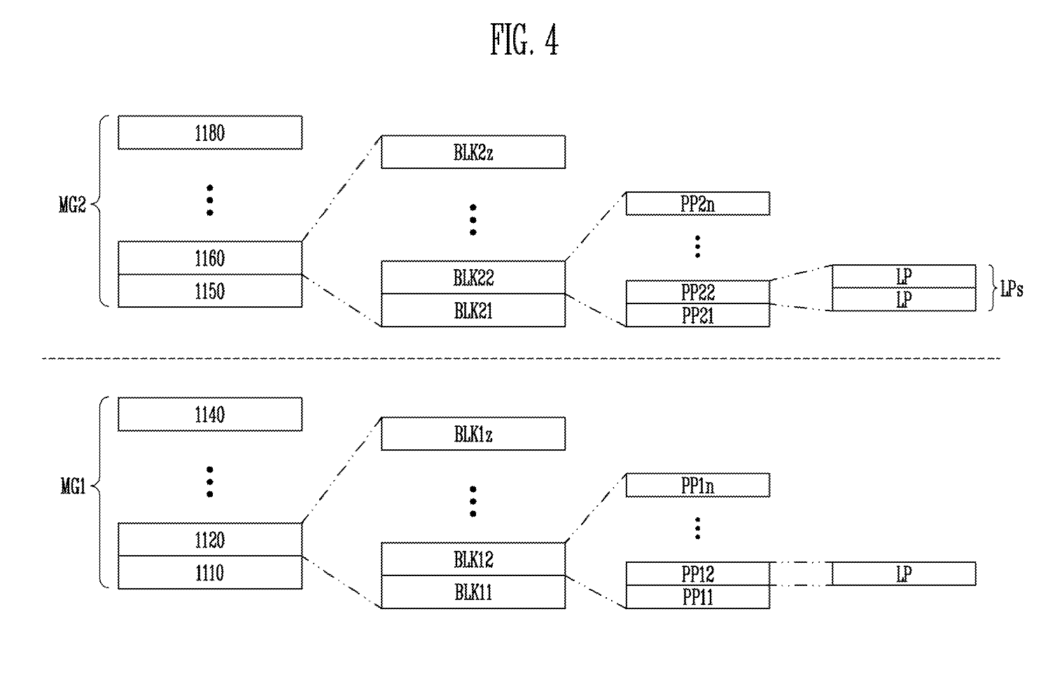

FIG. 4 is a diagram describing memory blocks included in each of the semiconductor memory devices 1110 to 11k0 of FIG. 3. In FIG. 4, for convenience of explanation, it will be assumed that eight semiconductor memory devices 1110 to 1180 are provided.

Referring to FIG. 4, the plurality of semiconductor memory devices 1110 to 1180 may be divided into first and second memory groups MG1 and MG2. The first memory group MG1 may be defined as single-level cells. The second memory group MG2 may be defined as multi-level cells.

The first memory group MG1 may include first to fourth semiconductor memory devices 1110 to 1140. Each of the semiconductor memory devices 1110 to 1140 of the first memory group MG1 may include first to z-th memory blocks BLK11 to BLK1z, each of which may include first to n-th physical pages PP11 to PP1n. Since memory cells of the first memory group MG1 are single-level cells, the first to n-th physical pages PP11 to PP1n may correspond to one logical page LP.

The second memory group MG2 may include fifth to eighth semiconductor memory devices 1150 to 1180. Each of the semiconductor memory devices 1150 to 1180 of the second memory group MG2 may include first to z-th memory blocks BLK21 to BLK2z, each of which may include first to n-th physical pages PP21 to PP2n. Since memory cells of the second memory group MG2 are multi-level cells, each of the first to n-th physical pages PP21 to PP2n may correspond to a plurality of logical pages LPs, for example, two logical pages LPs.

The inventive concept of the present invention may also be applied to the embodiment of FIG. 3. When each semiconductor memory device included in the memory system (1000, refer to FIG. 3) includes single-level cells or multi-level cells, this may mean that each memory block included in the memory system 1000 includes the single-level cells or the multi-level cells. For example, the memory block BLK12 of FIG. 4 may include single-level cells and, accordingly, each physical page of the memory block BLK12 may correspond to one logical page LP. For example, the memory block BLK22 may include multi-level cells and, accordingly, each physical page of the memory block BLK22 may correspond to the plurality of logical pages LPs. When the garbage collection is performed, at least one among the memory blocks included in the memory system 1000 may be selected as the victim block, and another one of the memory blocks included in the memory system 1000 may be selected as the target block.

Hereinafter, for convenience of explanation, an embodiment of the present invention will be described with reference to an embodiment of FIG. 1.

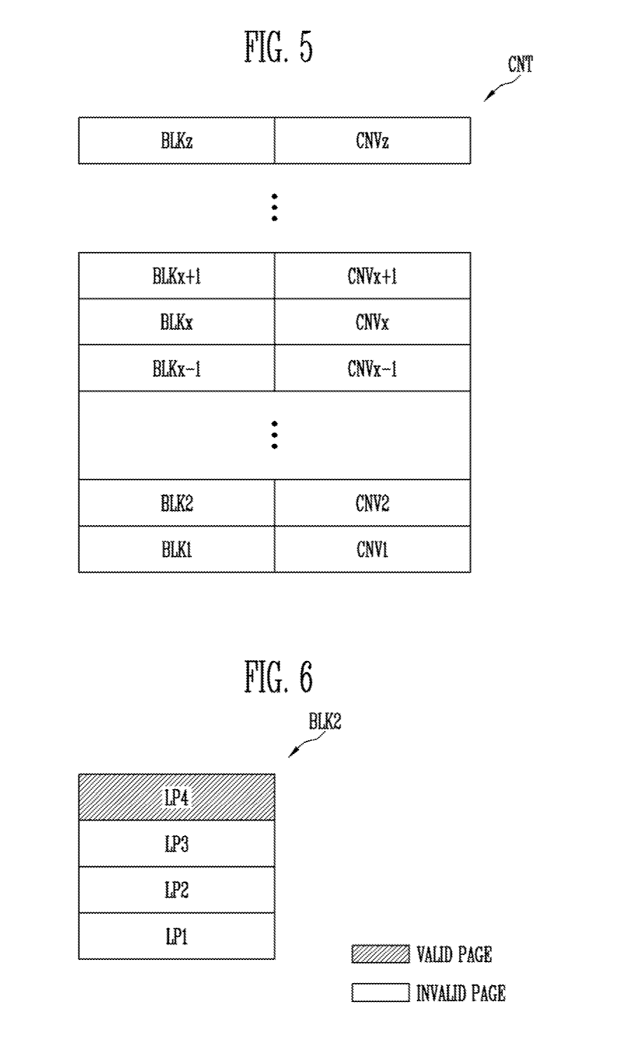

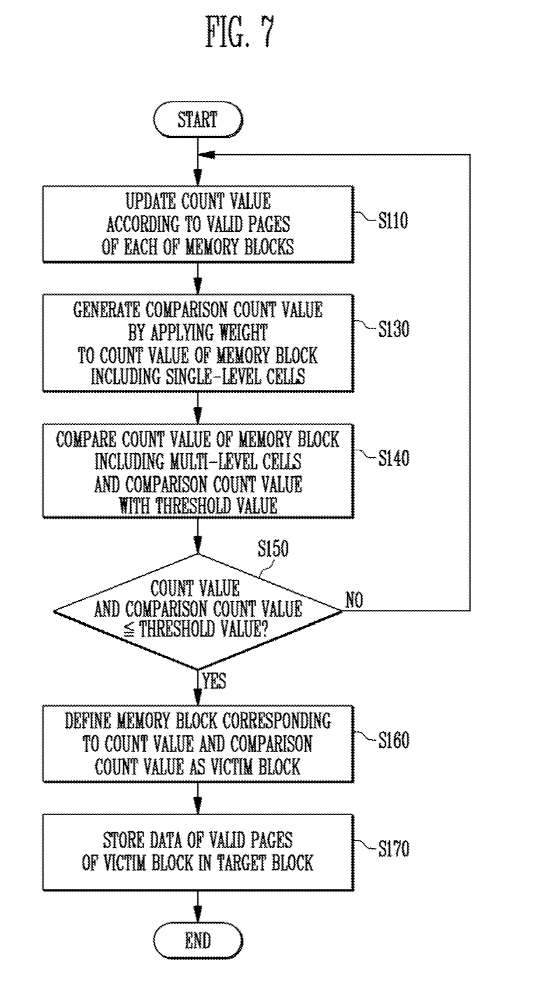

FIG. 5 is a table illustrating the count table CNT according to an exemplary embodiment of the present invention. FIG. 6 is a conceptual diagram illustrating logical pages included in any one BLK2 among memory blocks BLK1 to BLKz according to an exemplary embodiment of the present invention.

Referring to FIG. 5, the count table CNT may include first to z-th count values CNV1 to CNVz. Each of the first to z-th count values CNV1 to CNVz may correspond to each of the first to z-th memory blocks BLK1 to BLKz.

Each count value may represent the number of valid pages of a corresponding memory block. Referring to FIG. 6, the second memory block BLK2 may include a plurality of logical pages LP1 to LP4. In FIG. 6, for convenience of explanation, an example in which the second memory block BLK2 includes first to fourth logical pages LP1 to LP4 is illustrated. In FIG. 6, a shaded area represents the valid page, and non-shaded areas represent the invalid areas. The first logical page LP1 may correspond to the valid page, and the second to fourth logical pages LP2 to LP4 may correspond to the invalid pages. In this case, the count value CNV2 corresponding to the second memory block BLK2 may be set to 1.

FIG. 7 is a flowchart describing an operating method of a controller 200 according to an exemplary embodiment of the present invention.

Referring to FIGS. 1, 2, and 7, at step S110, the count values (CNV1 to CNVz, refer to FIG. 5) may be updated based on the valid pages of each of the memory blocks BLK1 to BLKz.

As an embodiment, the FTL 220 may decrease the count value of the memory block including the invalid page whenever the invalid page is generated by updating data based on an arbitrary logical block address. As an embodiment, the FTL 220 may adjust the count value based on the flag bits of data included in the logical pages of the memory block. As an embodiment, the FTL 220 may adjust the count value of each memory block based on the map table MPT. The first to z-th count values CNV1 to CNVz may be updated using various other methods.

At steps S130 to S170, the garbage collection may be performed.

At step S130, a comparison count value may be generated by applying weight to the count value of the memory block including the single-level cells. The comparison count value may have a value greater than a corresponding count value in the count table CNT. Since each of the memory cells of the memory blocks BLKx to BLKz may store two-bit data, the number of logical pages included in each of the memory blocks BLKx to BLKz may have a value two times greater than the number of the logical pages included in each of the memory blocks BLK1 to BLKx−1. In this case, the comparison count value may be determined by multiplying the count value of the memory block including the single-level cells by 2.

The inventive concept of the present invention may be also applied to when memory cells of the first memory block group BLKG1 are not the single-level cells. As an embodiment, suppose that p-bit data is stored in each of the memory cells of the memory blocks BLK1 to BLKx−1 and q-bit data is stored in each of the memory cells of the memory blocks BLKx to BLKz. Here, q may be an integer greater than p. In this case, the comparison count value of the corresponding memory block may be determined by multiplying the count value corresponding to each of the memory blocks BLK1 to BLKx−1 by a value obtained by dividing q by p.

At step S140, the count value of the memory block including the multi-level cells and the comparison count value of the memory block including the single-level cells may be compared with a threshold value.

At step S150, it is determined whether the count value and the comparison count value is less than or equal to the threshold value. When the count value and the comparison count value is less than or equal to the threshold value (YES), an operation at step S160 may be performed. When the count value and the comparison count value is greater than the threshold value (NO), the operations at steps S110 to S140 may be performed.

At step S160, the memory block corresponding to the count value and the comparison count value, which are less than or equal to the threshold value, may be defined as the victim block. When the count value of the memory block including the multi-level cells is less than or equal to the threshold value, the corresponding memory block may be selected as the victim block. When the comparison count value of the memory block including the single-level cells is less than or equal to the threshold value, the corresponding memory block may be selected as the victim block.

At step S170, data of the valid pages included in the selected victim block may be stored in the target block. Any one among the memory blocks BLK1 to BLKz may be selected as the target block. For example, the memory block including the memory cells corresponding to an erase state may be selected as the target block. Data of the valid pages may be stored in the memory cells having threshold voltages corresponding to the erase state. The controller 200 may control the semiconductor memory device 100 to read the data of the valid page, and receive the data read from the valid page. Further, the controller 200 may store the read data in the target block.

After this, the controller 200 may control the semiconductor memory device 100 to perform the erase operation on the victim block. The semiconductor memory device 100 may perform the erase operation on the victim block, and thus, the memory cells of the victim block may have threshold voltages corresponding to the erase state and the victim block may be set as an empty area in which data is not stored.

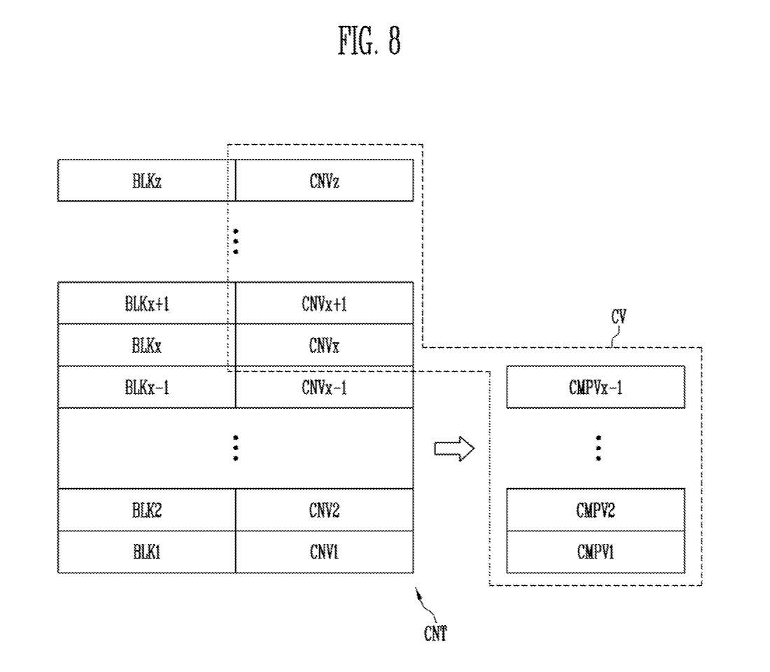

FIG. 8 is a diagram describing count values compared with a threshold value according to an exemplary embodiment of the present invention.

Referring to FIG. 8, the count table CNT may include the first to z-th count values CNV1 to CNVz corresponding to each of the first to z-th memory blocks BLK1 to BLKz.

The victim block may be selected from the first to z-th memory blocks BLK1 to BLKz (refer to FIG. 1). Comparison count values CMPV1 to CMPVx−1 may be generated by multiplying the count values CNV1 to CNVx−1 of the memory blocks BLK1 to BLKx−1 (refer to FIG. 2), including the single-level cells, by weight. When two-bit data are stored in each of the memory cells of the x-th to z-th memory blocks BLKx to BLKz (refer to FIG. 2), the comparison count values CMPV1 to CMPVx−1 may be determined by multiplying each of the count values CNV1 to CNVx−1 of the memory blocks BLK1 to BLKx−1 by 2. As another embodiment, when q-bit data is stored in each of the memory cells of the x-th to z-th memory blocks BLKx to BLKz, the comparison count values CMPV1 to CMPVx−1 may be determined by multiplying each of the count values CNV1 to CNVx−1 of the memory blocks BLK1 to BLKx−1 by q. The weight may be determined as a value obtained by dividing the bit number of data stored in the memory cells of the x-th to z-th memory blocks BLKx to BLKz by the bit number of data stored in the memory cells of the first to (x−1)-th memory blocks BLK1 to BLKx−1.

After this, the count values CV may be compared with the threshold value. Regarding the first to (x−1)-th memory blocks BLK1 to BLKx−1, the comparison count values CMPV1 to CMPVx−1 may be compared with the threshold value. Regarding the x-th to z-th memory blocks BLKx to BLKz, the x-th to z-th count values CNVx to CNVz may be compared with the threshold value.

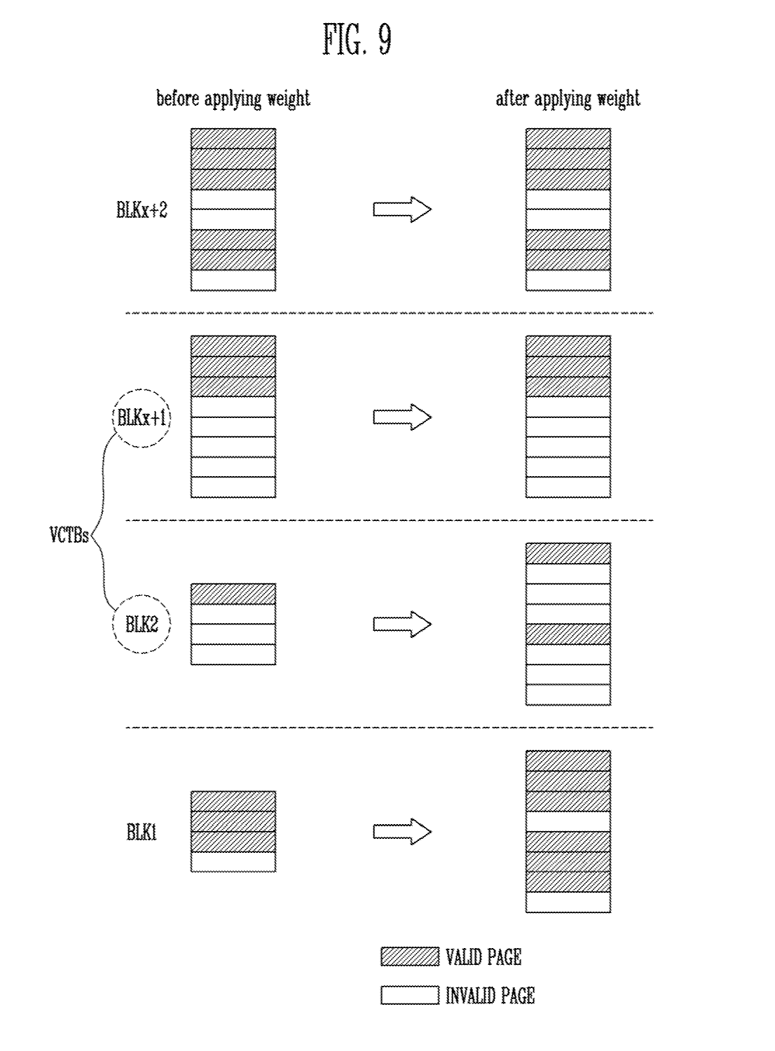

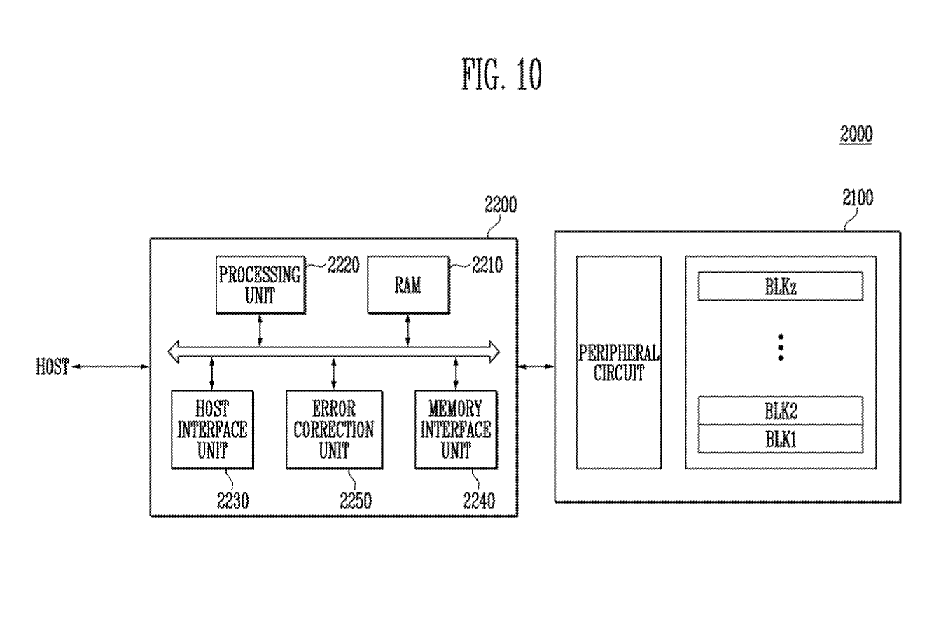

FIG. 9 is a conceptual diagram describing an example in which at least one victim block VCTB is selected according to an exemplary embodiment of the present invention. In the description of FIG. 9, for convenience of explanation, when selecting the victim blocks VCTBs, only the first, second, (x+1)-th, and (x+2)-th memory blocks BLK1, BLK2, BLKx+1, and BLKx+2 may be analyzed, and the analysis may be extended to the remaining memory blocks BLK3 to BLKx and BLKx+3 to BLKz. In the description with reference to FIG. 9, for convenience, it will be assumed that four physical pages are included in one memory block.

Referring to FIG. 9, since the first and second memory blocks BLK1 and BLK2 include single-level cells, one physical page may correspond to one logical page. Each of the first and second memory blocks BLK1 and BLK2 may include four logical pages. In FIG. 9, shaded areas represent the valid pages, and non-shaded areas represent the invalid pages. The first memory block BLK1 may include three valid pages and one invalid page. The second memory block BLK2 may include one valid page and three invalid pages.

The (x+1)-th and (x+2)-th memory blocks BLKx+1 and BLKx+2 may include multi-level cells. When each of the memory cells of the (x+1)-th and (x+2)-th memory blocks BLKx+1 and BLKx+2 stores two-bit data, one physical page may correspond to two logical pages. Each of the (x+1)-th and (x+2)-th memory blocks BLKx+1 and BLKx+2 may include eight logical pages. In FIG. 9, the (x+1)-th memory block BLKx+1 may include three valid pages and five invalid pages. The (x+2)-th memory block BLKx+2 may include five valid pages and three invalid pages.

Suppose that the number of the valid pages of each memory block is compared with the threshold value which is set to 4 before the weight is applied. The first, second, and (x+1)-th memory blocks BLK1, BLK2, and BLKx+1 having a number of valid pages that is less than or equal to 4 may be selected as the victim blocks. At this time, the second and (x+1)-th memory blocks BLK2 and BLKx+1 may include a half or less valid pages among the total number of the logical pages, whereas the first memory block BLK1 may include a half or more valid pages among the total number of the logical pages. Nevertheless, the first memory block BLK1 may be selected as the victim block. This may mean that the first memory block BLK1 is selected as the victim block although the relatively large number of logical pages included in the first memory block BLK1 are still valid. Further, this may mean that the first memory block BLK1 may be selected as the victim block without providing sufficient time for updating data corresponding to the logical pages of the first memory block BLK1. Moreover, this may mean that the garbage collection is frequently performed compared with when the first memory block BLK1 is selected as the victim block after the data corresponding to the logical pages of the first memory block BLK1 is updated sufficiently. When the memory block including the single-level memory cells is used as a buffer area for the memory block including the multi-level memory cells, the probability in which the data corresponding to the logical pages of the first memory block BLK1 is updated is increased. Accordingly, the garbage collection may be performed more frequently when the number of valid pages of the first memory block BLK1 is compared with the threshold value without applying the weight.

According to an embodiment of the present invention, a weight may be applied to the count value of the memory block Including the memory cell for storing a small bit number of data when selecting the victim block. The number of valid pages corresponding to each of the first and second memory blocks BLK1 and BLK2 may be multiplied by 2. After the weight is applied, the first memory block BLK1 may include six valid pages. The second memory block BLK2 may include two valid pages. That is, the comparison count values (CMPV1 and CMPV2, refer to FIG. 8) of the first and second memory blocks BLK1 and BLK2 may be 6 and 2, respectively.

Regarding the first and second memory blocks BLK1 and BLK2, the comparison count values CMPV1 and CMPV2 may be compared with the threshold value, and regarding the (x+1)-th and (x+2)-th memory blocks BLKx+1 and BLKx+2, the count values (CNVx+1 and CNVx+2, refer to FIG. 8) may be compared with the threshold value. The second and (x+1)-th memory blocks BLK2 and BLKx+1 having count values that are less than or equal to the threshold value may be selected as the victim blocks VCTBs. Since the first comparison count value CMPV1 is greater than the threshold value, the first memory block BLK1 may not be selected as the victim block.

According to an embodiment of the present invention, the weight may be applied to the count value of the memory block including the single-level cells, the comparison count value may be generated, and the comparison count value may be compared with the threshold value. The count value of the memory block including the multi-level cells may be compared with the threshold value without applying the weight. Accordingly, regardless of whether each memory block includes the single-level cells or the multi-level cells, the victim block may be selected in response to a ratio in which the valid pages among the logical pages of each memory block occupy. Further, garbage collection may be efficiently performed.

FIG. 10 is a block diagram illustrating a memory system 2000 according to an exemplary embodiment of the present invention.

Referring to FIG. 10, the memory system 2000 may include a semiconductor memory device 2100 and a controller 2200.

The semiconductor memory device 2100 may have the same configuration and operation as the semiconductor memory device 100 described with reference to FIG. 1. Hereinafter, duplicated descriptions will be omitted.

The controller 2200 may be connected to a host and the semiconductor memory device 2100. The controller 2200 may include a RAM 2210, a processing unit 2220, a host interface unit 2230, a memory interface unit 2240, and an error correction unit 2250.

The RAM 2210 may serve as at least one among an operating memory of the processing unit 2220, a cache memory between the semiconductor memory device 2100 and the host, and a buffer memory between the semiconductor memory device 2100 and the host. The processing unit 2220 may control various operations of the controller 2200. The processing unit 2220 and the RAM 2210 may have the same configuration and operation as the FTL 220 described with reference to FIG. 1. For example, a program code for the FTL 220 may be stored in the semiconductor memory device 2100, the program code may be loaded on the RAM 2210, and the processing unit 2220 may perform the operation of the FTL 220 by executing the program code loaded on the RAM 2210. For example, the processing unit 2220 may perform the operation of the FTL 220 by driving firmware.

The host interface unit 2230 may include a protocol for performing a data exchange between the host and the controller 2200. As an embodiment, the controller 2200 may communicate with the host through at least one among various protocols such as a Universal Serial Bus (USB) protocol, a MultiMediaCard (MMC) protocol, a Peripheral Component Interconnect (PCI) protocol, a PCI-Express (PCI-E) protocol, an Advanced Technology Attachment (ATA) protocol, a Serial ATA (SATA) protocol, a Parallel ATA (PATA) protocol, a Small Computer System Interface (SCSI) protocol, an Enhanced Small Disk Interface (ESDI) protocol, an Integrated Drive Electronics (IDE) protocol, an a private protocol, etc.

The memory interface unit 2240 may interface with the semiconductor memory device 2100. For example, the memory interface unit 2240 may be a NAND interface unit or a NOR interface unit.

The error correction unit 2250 may detect and correct an error of data received from the semiconductor memory device 2100 using an error correcting code (ECC).

The controller 2200 and the semiconductor memory device 2100 may be integrated into a single semiconductor device. As an embodiment, the controller 2200 and the semiconductor memory device 2100 may configure a memory card by being integrated into a single semiconductor device. For example, the controller 2200 and the semiconductor memory device 2100 may configure a memory card such as a personal computer memory card International association (PCMCIA), a compact flash (CF) card, a smart media (SM) card (SMC), a memory stick, a multimedia card (MMC), a reduced size MMC (RS-MMC), a micro-MMC, a secure digital (SD) card, a mini-SD, a micro-SD, an SDHC, a universal flash storage (UFS) device, etc.

The controller 2200 and the semiconductor memory device 2100 may configure a solid state drive (SSD) by being Integrated into a single semiconductor device. The SSD may include a storage device configured to store data in a semiconductor memory. When the memory system 2000 serves as an SSD, the operating speed of the host connected to the memory system 2000 may dramatically improve.

As another exemplary embodiment, the memory system 2000 may be provided as one among various components of an electronic device such as a computer, an ultra mobile personal computer (UMPC), a workstation, a net-book, a personal digital assistant (PDA), a portable computer, a web tablet, a wireless phone, a mobile phone, a smart phone, an e-book, a portable multimedia player (PMP), a portable game console, a navigation device, a black box, a digital camera, a three-dimensional television, a digital audio recorder, a digital audio player, a digital picture recorder, a digital picture player, a digital video recorder, a digital video player, a device for wirelessly transmitting and receiving information, one among various electronic devices configuring a home network, one among various electronic devices configuring a computer network, one among various electronic devices configuring a telematics network, a radio frequency identification (RFID) device, or one among various components configuring a computing system.

As an exemplary embodiment, the semiconductor memory device 2100 or the memory system 2000 may be packaged in various types of packages. For example, the semiconductor memory device 2100 or the memory system 2000 may be packaged and mounted in a manner such as a package on package (PoP), a ball grid array (BGA), a chip scale package (CSP), a plastic leaded chip carrier (PLCC), a plastic dual in-line package (PDIP), a die in waffle pack (DWP), a die in wafer form (DWF), a chip on board (COB), a ceramic dual in-line package (CERDIP), a plastic metric quad flat package (MQFP), a thin quad flat package (TQFP), a small outline integrated circuit (SOIC), a shrink small outline package (SSOP), a thin small outline package (TSOP), a system in package (SIP), a multi chip package (MCP), a wafer-level fabricated package (WFP), a wafer-level processed stack package (WSP), or the like.

According to an embodiment of the present invention, regardless of whether each memory block includes single-level cells or multi-level cells, the victim block may be selected based on a ratio in which the valid pages among the logical pages of each memory block occupy. Accordingly, the garbage collection may be efficiently performed.

According to an embodiment of the present invention, the operating speed of a memory system may be increased.

The technical spirit of the present invention has been described with reference to exemplary embodiments in detail, but it should be noted that the embodiments are used for the description only and are not intended to limit the scope of the present invention. Therefore, it will be understood by those of ordinary skill in the art that various changes in form and detail may be made without departing from the spirit and scope of the present invention as defined by the following claims.

What is claimed is:

1. A method of operating a semiconductor memory device including a plurality of memory blocks, the method comprising:
determining the number of valid pages of a first memory block including single-level cells as a first count value;
determining the number of valid pages of a second memory block including multi-level cells as a second count value;
applying a weight to the first count value to generate a comparison count value which is greater than the first count value; and
defining at least one of the first and second memory blocks as a victim block by comparing the comparison count value and the second count value with a threshold value.

2. The method of claim 1, wherein the comparison count value is obtained by multiplying the first count value by 2 when two-bit data are stored in each of the memory cells of the second memory block.

3. The method of claim 1, wherein the comparison count value is obtained by multiplying the first count value by n when n-bit data is stored in each of the memory cells of the second memory block, where n is an integer which is greater than 2.

4. The method of claim 1, wherein the first memory block is the victim block when the comparison count value is less than or equal to the threshold value.

5. The method of claim 1, wherein the second memory block is the victim block when the second count value is less than or equal to the threshold value.

6. The method of claim 1, further comprising:
storing data of valid pages of the victim block in a third memory block among the plurality of memory blocks.

7. The method of claim 6, further comprising:
erasing the data of the valid pages of the victim block.

8. A memory system comprising:
at least one semiconductor memory device including a first memory block including single-level cells and a second memory block including multi-level cells; and
a controller suitable for determining the number of valid pages of the first memory block as a first count value and the number of valid pages of the second memory block as a second count value, generating a comparison count value which is greater than the first count value by applying a weight to the first count value, and defining at least one of the first and second memory blocks as a victim block by comparing the comparison count value and the second count value with a threshold value.

9. The memory system of claim 8, wherein the controller generates the comparison count value by multiplying the first count value by 2 when two-bit data are stored in each of the memory cells of the second memory block.

10. The memory system of claim 8, wherein the controller generates the comparison count value by multiplying the first count value by n when n-bit data is stored in each of the memory cells of the second memory block, where n is an integer which is greater than 2.

11. The memory system of claim 8, wherein the controller defines the first memory block as the victim block when the comparison count value is less than or equal to the threshold value.

12. The memory system of claim 8, wherein the controller defines the second memory block as the victim block when the second count value is less than or equal to the threshold value.

13. The memory system of claim 8, wherein the semiconductor memory device further comprises;
a third memory block in which the controller stores data of valid pages of the victim block.

14. The memory system of claim 8, wherein the controller comprises:
a processing unit; and
a random access memory (RAM),
wherein the processing unit stores a map table including a mapping relation between physical block addresses and logical block addresses, which correspond to the valid pages of the first and second memory blocks, in the RAM.

15. The memory system of claim 14, wherein the processing unit stores the first and second count values in the RAM, and adjusts the first and second count values when each of the valid pages of the first and second memory blocks is invalidated.

16. The memory system of claim 15, wherein the processing unit decreases the first and second count values when each of the valid pages of the first and second memory blocks is invalidated.

17. A memory system comprising:
at least one semiconductor memory device including a first memory block including each of memory cells of storing n-bit data and a second memory block including each of memory cells storing m-bit data, wherein n is an integer, and m is an integer greater than n; and
a controller suitable for determining the number of valid pages of the first memory block as a first count value and the number of valid pages of the second memory block as a second count value, generating a comparison count value which is greater than the first count value by applying a weight to the first count value, and defining at least one of the first and second memory blocks as a victim block by comparing the comparison count value and the second count value with a threshold value.

18. The memory system of claim 17, wherein the weight is a value obtained by dividing the m into the n.

19. The memory system of claim 17, wherein the controller defines the first memory block as the victim block when the comparison count value is less than or equal to the threshold value, and defines the second memory block as the victim block when the second count value is less than or equal to the threshold value.

20. The memory system of claim 17, wherein the controller comprises:
a random access memory (RAM) suitable for including a map table storing a mapping relation between physical block addresses and logical block addresses, which correspond to the valid pages of the first and second memory blocks, and a count table storing the first and second count values; and
a processing unit suitable for updating the mapping relation, and decreasing the first and second count values when each of the valid pages of the first and second memory blocks is invalidated.
